(19) United States
(12) Patent Application Publication
(10) Pub. No.: US 2009/0231166 A1
(43) Pub. Date: Sep. 17, 2009

(54) TEKGLOW

(76) Inventor: Daniel Peck, Dayton, OH (US)

Correspondence Address: DANIEL Peck, 4600 OAKDELL Ave, DAYTON, OH, 45432, US

(21) Appl. No.: 11/923,530

(22) Filed: Mar. 13, 2008

(51) Int. Cl. H03K 17/94

(52) U.S. Cl. 341/22

(57) ABSTRACT

The TekGlow invention allows the ability to see keyboard keys, keypads or keyboard key markings in the dark without the use of direct power sources like electricity or batteries. All that is required for stated item/s to glow in the dark is that they must be exposed to a light source like a lamp or sunlight for a period of time. They would need to be re-introduced to a light source again to glow in the dark for more glowing time.

A process whereby items with keyboards would have its keys, letterings and/or graphic information made of entirely, or in part, with a glowing agent substance that would make them glow in the dark for a period of time when exposed to a light source for a period of time. The light source could either be natural or artificial.

The glowing agent substance consists of chemicals like Photoluminescent, Phosphorescent, Zinc Sulfide, Strontium Aluminate, Glowing Dust or similar glowing agent substances.

This invention would eliminate the use of an electrical source to see related items in the dark.

The glowing colors for said related items would be available in various color schemes.

1. The claim to this invention called Tekglow, is for use on all items using keyboards or keypads, including, but not limited to; Computer Keyboards and Cordless or Cellular Phone Keyboards/ Keypads.
